(19) United States
(12) Patent Application Publication
(10) Pub. No.: US 2003/0072195 A1
(43) Pub. Date: Apr. 17, 2003

(54) Semiconductor memory device and fabrication method

(76) Inventor: Thomas Mikolajick, Dresden (DE)

Correspondence Address: LERNER AND GREENBERG P.A., Post Office Box 2480, Hollywood, FL, 33022-2480, US

(21) Appl. No.: 10/167,789

(22) Filed: Jun. 12, 2002

(30) Foreign Application Priority Data
Jun. 12, 2001 (DE) 101 28 482.9

(51) Int. Cl. G11C 7/00

(52) U.S. Cl. 365/200

(57) ABSTRACT

A semiconductor memory device and fabrication method For fabricating compact and functionally reliable semiconductor devices with a phase conversion storage effect is described. During a formation of a contact hole for a storage medium and an electrode, margin areas thereof are constructed with corresponding spacer elements by a spacer technique, in order to reduce the lateral extent of the contact hole and thus to reduce the contact surface to the storage medium. In this way, the storage medium can also be reliably driven by a MOSFET.

### BACKGROUND OF THE INVENTION

2. Field of the Invention

The invention relates to a semiconductor memory device having at least one storage element with a phase conversion storage effect. The memory has a first or bottom access electrode, a second or top access electrode, and at least partly substantially between these, a storage medium with a phase-dependent ohmic resistance in contact with the access lines. These features form a storage element constructed in a semiconductor substrate, in a first insulation layer and/or surface region thereof. The first or bottom access electrode is at least partly embedded in and/or covered by a second insulation layer and a recess is formed in the second insulation layer. The recess is filled with a material for the storage medium such that the material is substantially in conductive contact with an open surface region of the first access electrode, whereby the recess is a contact hole or similar structure for the storage medium and/or for the second access electrode.

With the progress of modern semiconductor memory technologies, new kinds of memory concepts are being introduced. These relate particularly to non-volatile memories. In these, the storage media that are to be provided in the respective memory cells are selected and applied in view of their physical characteristics in phase conversions. Thus, for example, there are known non-volatile memories in which the storage medium shifts from a low-impedance state, potentially a crystalline state, into a high-impedance state, potentially an amorphous state, in a phase conversion process. In this concept, a material having two stable phases, namely a high-impedance amorphous phase and a low-impedance crystalline phase, is utilized as the storage medium. The material can be switched back and forth in reversible fashion between the two phases by electrical impulses. The corresponding resistance changes in the phase transition between the amorphous and crystalline phases are utilized for storing information.

Though what are known as chalcogenides have customarily been used in this capacity, in principle any material that allows a reversible changeover between a high-impedance state and a low-impedance state can be utilized as the storage medium in the non-volatile memories.

In order to be able to realize non-volatile memories with high integration densities with this concept, it is necessary that the current required for the corresponding phase conversion, for instance for the heating of the material to a temperature above the phase conversion temperature, be suppliable by a selection element or selection device with a minimal structural size.

### SUMMARY OF THE INVENTION

It is accordingly an object of the invention to provide a semiconductor memory device and a fabrication method that overcome the above-mentioned disadvantages of the prior art methods and devices of this general type, which has a phase conversion storage effect that can be realized with a particularly high integration density and nevertheless high functional reliability.

With the foregoing and other objects in view there is provided, in accordance with the invention, a method for fabricating a semiconductor memory device having at least one memory cell with a phase conversion storage effect. The method includes providing a semiconductor substrate having a surface region and a first insulation layer disposed on the surface region, forming a first access electrode on the first insulation layer, applying a second insulation layer which at least covers the first access electrode, forming a recess in the second insulation layer such that at least a portion of a surface region of the first access electrode is exposed resulting in a freely accessible surface region, and performing a spacer technique for forming a spacer element at least along margin regions of the recess. The spacer element reduces a lateral extent of the recess and of the freely accessible surface region of the first access electrode. Furthermore, the spacer element reduces a contact surface available to a storage medium to be provided. The recess is filled with a material for forming the storage medium, such that the material is in substantially conductive contact with the freely accessible surface region of the first access electrode. A second access electrode is formed on the storage medium such that the storage medium is substantially between the first access electrode and the second access electrode. The storage medium has a phase-dependent ohmic resistance in contact with the first and second access electrodes.

In the species-related method for fabricating the semiconductor memory device with at least one memory element which exhibits a phase conversion storage effect, particularly a phase conversion resistive storage element, the first or bottom access electrode, the second or top access electrode, and an at least partly substantially interposed storage medium with a phase-dependent ohmic resistance in contact with the access electrodes are realized in a semiconductor substrate, in an insulation layer, and/or a surface region thereof, for the respective memory element. In the first step in this process, at least the first access electrode is embedded in a second insulation layer and covered by the same. Next, in accordance with the species, a recess is made in the second insulation layer, so that at least part of the surface region of the first access electrode is exposed in order to form a contact hole or similar structure for the storage medium and/or for the second access electrode. Lastly, in accordance with the species, the recess is filled with a material for forming the storage medium, such that this is in substantially conductive contact with the open surface region of the first access electrode.

The inventive method for fabricating the semiconductor storage device with at least one phase conversion storage element is characterized in that, after the recesses are formed in the second insulation layer for purposes of exposing the surface region of the first access electrode, at least margin or edge regions of the recess in the second insulation layer are formed by a spacer technique with the aid of a respective spacer element, in order to reduce the lateral extent of the recess and the freely accessible portion of the surface region of the first access electrode, and thus to reduce the contact area for the storage medium that is to be provided.

It is thus a basic idea of the present invention to reduce the contact surface between the first access electrode and the phase conversion storage medium by narrowing the dimensions of a contact hole that is provided in the second insulation layer by depositing spacer elements or spacer regions that extend substantially vertically. The diameter of the contact hole is thus narrowed, and the freely accessible contact surface that afterward will be covered with a storage medium is reduced. The advantage of this is that the material of the storage medium that must undergo a phase conversion, for example by heating by a current flow, is reduced. In this way, the electrical or thermal power that must be applied can also be reduced. The volume of the storage medium that is to undergo phase conversion being so reduced by selecting the spacer elements and their dimensions accordingly, it is now possible to achieve a range of electrical or thermal power that is realizable by a switching transistor with a minimal structural size, such as a high-density integrated MOSFET structure.

In the extreme case, the storage medium volume that is to undergo phase conversion can be reduced such that the power that will be applied can be applied without a separate selection transistor or access transistor per memory cell. This can be a matter of what is known as a cross-point configuration, wherein portions of provided access lines, such as word lines or bit lines, form the access electrodes.

In the foregoing and following description, an insulation layer also refers to what is known as a passivation layer or the like. What is essential for the insulation layer is that, as such, it exerts a substantially insulating effect. Conductive regions such as metallization regions or metallization layers can also be locally provided in the insulation layer for interconnection purposes.

According to a particularly preferred embodiment of the inventive method, the spacer elements are realized in that, first, a material layer for the spacer elements is formed in a substantially two-dimensional, conformal, large-area and/or surface-wide deposition, in such a way that margin regions and floor regions of the recesses in the second insulation layer are substantially covered.

It is further provided that the material layer for the spacer elements is etched back anisotropically and/or directionally in such a way that substantially laterally extending material regions of the material layer for the spacer elements are substantially removed, particularly on the surface region of the second insulation layer and/or of the floor region of the recess. It is further provided that substantially vertically extending material regions of the material layer for the spacer elements remain specifically as spacer elements.

By these steps, the narrowing of the recesses of the contact holes can be practically controlled by the thickness of the constructed material region for the spacer elements. Because the achievable layer thicknesses can be controlled well below the maximum resolution of a lithographic technique, in the forming of the recesses in the second insulation layer, i.e. the forming of a primary contact hole with minimal extent (on the order of magnitude of the minimal structural size or feature size of the utilized lithographic method), it is possible to select a layer thickness of less than half the feature size for the material layer of the spacer elements, and thus to narrow the contact hole to a lateral extent below the lithographically possible resolution. Thus, the contact surfaces between the electrodes or access electrodes and the actual storage medium can be below the lithographically achievable resolution.

A particularly advantageous embodiment of the inventive method provides that the material layer for the spacer elements is formed by deposition, particularly isotropic and/or conformal deposition.

SiO₂, BPSG, a photo imide, Si₃N₄ and/or a similar substance, or combinations thereof, are utilized for the material layer for the spacer elements.

According to another preferred embodiment of the inventive fabrication method, particularly small contact surfaces emerge between the first access electrode and the storage medium that is to be provided, when the material layer for the spacer elements and/or the spacer elements are constructed with a thickness which is less than half the maximum extent of the recess in the second insulation layer, particularly half the feature size of the utilized etching or lithography technique.

Another preferred embodiment of the inventive method provides that the first access electrode is constructed with a limited lateral extent that substantially corresponds to the feature size of an applied lithography technique or the like. This makes possible a higher integration density overall.

In another preferred embodiment of the inventive method, the first access electrodes are formed by first depositing a material region for them in a substantially two-dimensional, large-area and/or surface-wide fashion on the semiconductor substrate or the like, on the first insulation layer and/or surface region thereof, and then partly removing it by a lithography or etching technique; whereby the first access electrode is respectively formed at defined locations.

The location selected as the defined location is a region directly above and in contact with a surface region of a contact region or plug region provided in the semiconductor substrate or the like, in the first insulation layer and/or a surface region thereof, for the purpose of providing contact with an access line, a selection device (particularly a MOSFET), or a similar device.

According to another embodiment of the inventive method, a source/drain region of a selection device that is to be provided (particularly a MOSFET or similar device), or a portion thereof, is utilized as the first access electrode device, whereby a metallic intermediate layer is formed, in particular. This approach omits the forming of an explicit plug region or contact region for contacting the source/drain region of the selection transistor with the explicit first access electrode. The source/drain region of the selection device serves as the first or bottom access electrode, and from a spatial perspective the storage medium takes the place of the contact region or plug region.

Alternatively or additionally, first and second access lines, particularly word lines and/or bit lines or similar devices, are formed for accessing the individual storage elements. It is further provided that respective portions of the first access line, particularly the word line, and/or of the second access line, particularly the bit line, are provided as the first or bottom access electrode and the second or top access electrode, respectively, specifically in a crossing region of the access lines. This approach substantially avoids the forming and processing of a selection device. The power that is required for the phase conversion of the storage medium is made available directly by the access lines or access line devices, assuming of course that the storage medium volume that is to undergo phase conversion is constructed small enough that the power that can be transported directly over the lines is sufficient for the phase conversion of the storage medium volume that is to be charged.

Specifically with this configuration, it is possible according to another embodiment of the method to dispose or organize a plurality of memory cells in a layered fashion in several storage layers that are stacked substantially directly on top of one another.

The inventive solution with respect to the device will now be described. The semiconductor memory device contains a semiconductor substrate having a surface, a first insulating layer disposed on the semiconductor substrate, a first access electrode disposed on the first insulating layer, and a second insulating layer disposed on the first insulating layer and covers the first access electrode. The second insulating layer has a recess formed therein in an area of the first access electrode and uncovers a free surface area of the first access electrode. A spacer element is disposed at least on edge regions of the recess such that a lateral extent of the recess and of the free surface area of the first access electrode, emerge reduced, to a value below a minimum structural size of an applied technique used being a lithograph technique or an etching technique. A material functioning as a storage medium and has a phase-dependent ohmic resistance fills the recess. The storage medium is in conductive contact with the free surface area of the first access electrode. A second access electrode is disposed on the storage medium. The first access electrode, the storage medium and the second access electrode define a storage element.

It is inventively provided that at least first edge or margin regions of the recess and/or of the contact hole in the second insulation layer are respectively formed particularly by a spacer technique with the aid of a spacer element, so that the lateral extent or expanse of the recess and/or the contact hole and of the freely accessible portion of the surface region of the first access electrode, and thus of the contact surface of the provided storage medium, emerge reduced, namely to a value below the minimal structural size or feature size of a utilized lithography technique.

In a particularly preferred embodiment of the inventive semiconductor memory device, it is provided that the spacer elements are composed of SiO₂, BPSG, a photo imide, Si₃N₄ and/or a similar substance.

In another preferred embodiment of the inventive semiconductor memory device, it is provided that the first access electrode has a limited lateral extent that substantially corresponds to the structural size or feature size of a utilized lithography or etching process or similar process, at least by an order of magnitude.

It is also advantageous that a source/drain region of a provided selection transistor or a provided selection device, particularly a MOSFET or similar device, is constructed as the first or bottom access electrode, or as a portion thereof, whereby a metallic intermediate layer can be formed.

Alternatively or additionally, first and second access lines, particularly word lines and/or bit lines or similar devices, can be constructed for accessing the individual storage elements. It is further provided that a portion of a first access line, particularly a word line or similar device, and/or of a second access line, particularly a bit line or similar device, are constructed as the first or bottom and second or top access electrodes, respectively, particularly in a crossing region of the access line. This embodiment avoids the need for a selection transistor to apply the power for the phase conversion of the storage medium. This presumes that the storage medium that is to undergo phase conversion has a correspondingly reduced volume.

It is particularly advantageous when a plurality of memory cells are disposed and/or organized in storage layers that are stacked substantially directly on top of one another.

In known fabrication methods for semiconductor memory devices with phase conversion storage elements, the contact surfaces between the access electrodes that are to be provided and the material of the storage medium that is to undergo phase conversion are defined by the dimensioning of the contact hole or via hole and the thickness of the electrode. Owing to the limited resolution power of contemporary lithography or of etching techniques, the emerging contact surfaces and storage medium volumes that are to undergo phase conversion necessitate control currents and corresponding electrical powers that typically cannot be applied by miniaturized MOSFETs. It is therefore necessary to utilize selection transistor devices with larger dimensions. This ultimately hinders the development of optimally high-density integrated semiconductor memory devices on the basis of what are known as phase conversion memories.

The inventive fabrication method retains the contacting in a floor of the contact hole, such as is known from metallization techniques. However, the contact surface between the access electrode and the storage medium can be appreciably reduced. This is accomplished by reducing or narrowing the diameter of the contact holes with the aid of a spacer technique, independent of the structure defined by the photolithography. Furthermore, utilizing a different material for the spacer than for the remaining insulation makes possible an additional degree of freedom in the optimization of the thermal coupling between the material for phase conversion and the surrounding structures. A basic idea of the present invention is thus the application of a spacer technique to the reduction of the diameter of contact holes to below the lithographically resolvable structural size.

With the foregoing and other objects in view there is further provided, in accordance with the invention, a semiconductor memory device. The memory device contains a semiconductor substrate having a surface, a first access electrode disposed in the semiconductor substrate and functioning as part of a source/drain region of a selection transistor, and an insulating layer disposed on the semiconductor substrate covering the first access electrode. The insulating layer has a recess formed therein in an area of the first access electrode and uncovers a free surface area of the first access electrode. A spacer element is disposed at least on edge regions of the recess such that a lateral extent of the recess and of the free surface area of the first access electrode, emerge reduced, to a value below a minimum structural size of an applied technique used being either a lithograph technique or an etching technique. A material functioning as a storage medium and has a phase-dependent ohmic resistance fills the recess. The storage medium is in conductive contact with the free surface area of the first access electrode. A second access electrode is disposed on the storage medium. The first access electrode, the storage medium and the second access electrode define a storage element.

Other features which are considered as characteristic for the invention are set forth in the appended claims.

Although the invention is illustrated and described herein as embodied in a semiconductor memory device and a fabrication method, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1A is a diagrammatic, sectional view of a semiconductor memory device which has been fabricated according to the invention;

FIG. 1B is a plan view of the semiconductor memory device according to the invention;

FIG. 2A is a sectional view of the semiconductor memory device which is generated by a fabrication technique known in the prior art;

FIG. 2B is a plan view of the semiconductor memory device according to the prior art;

FIGS. 3-9 are sectional views of intermediate stages in the fabrication of the semiconductor memory device according to the invention.

### DESCRIPTION OF THE PREFERRED EMBODIMENTS

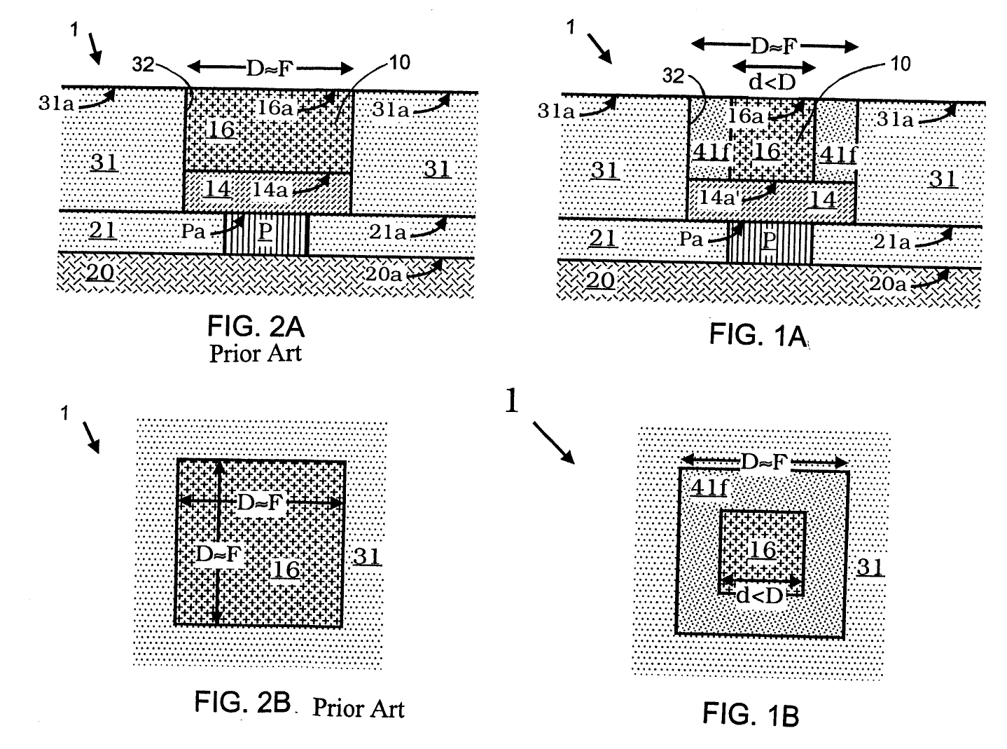

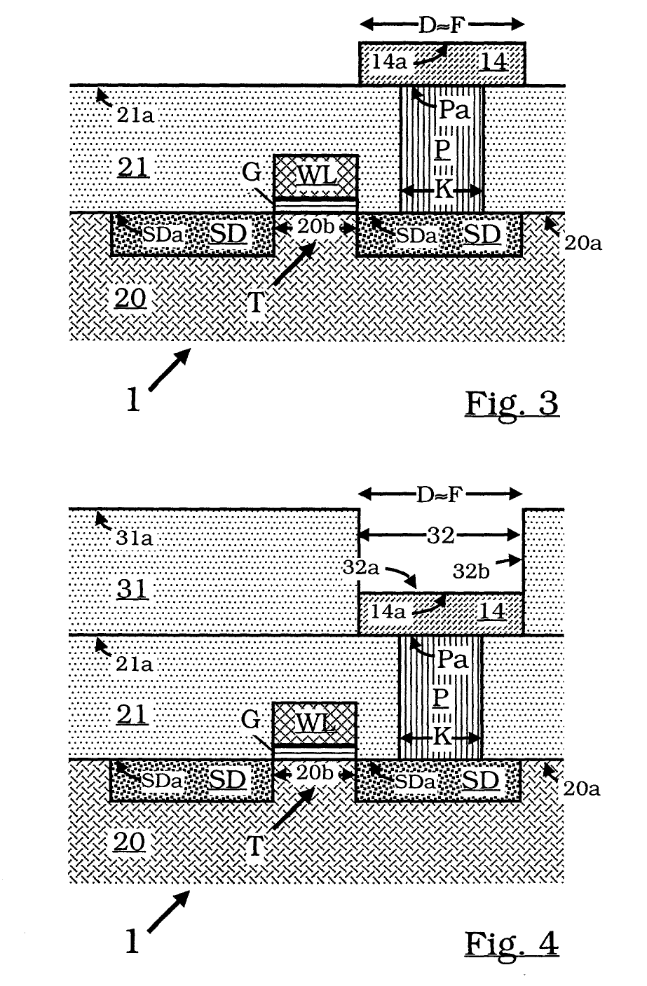

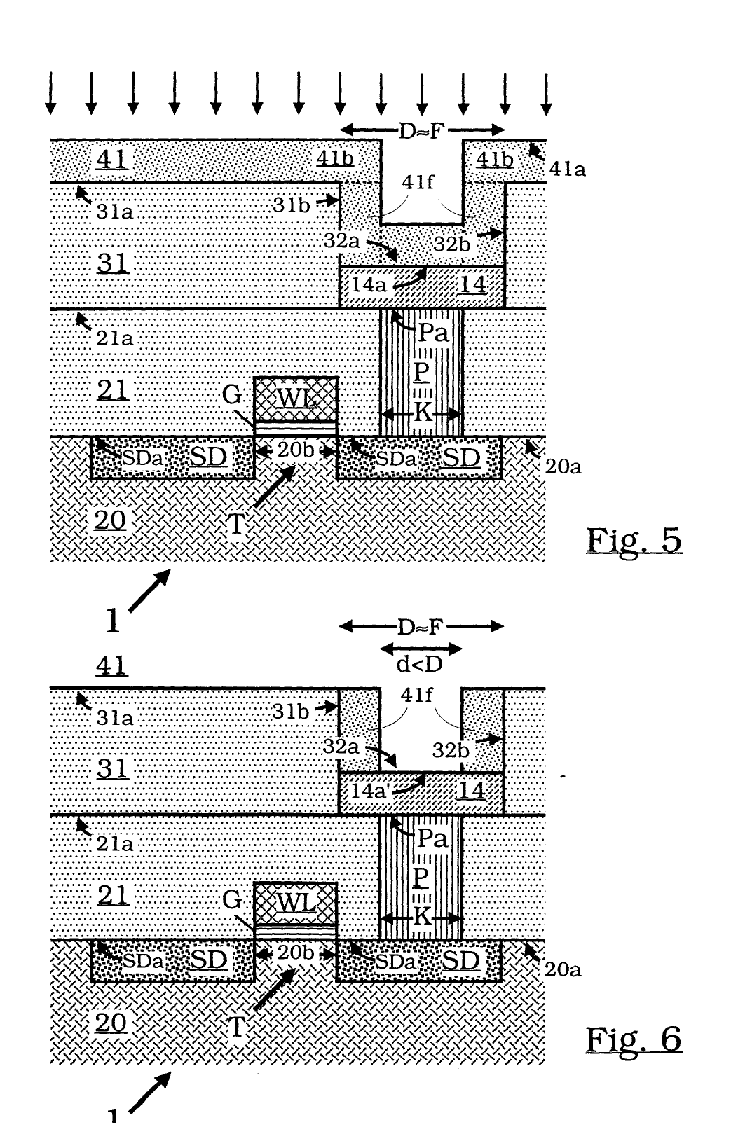

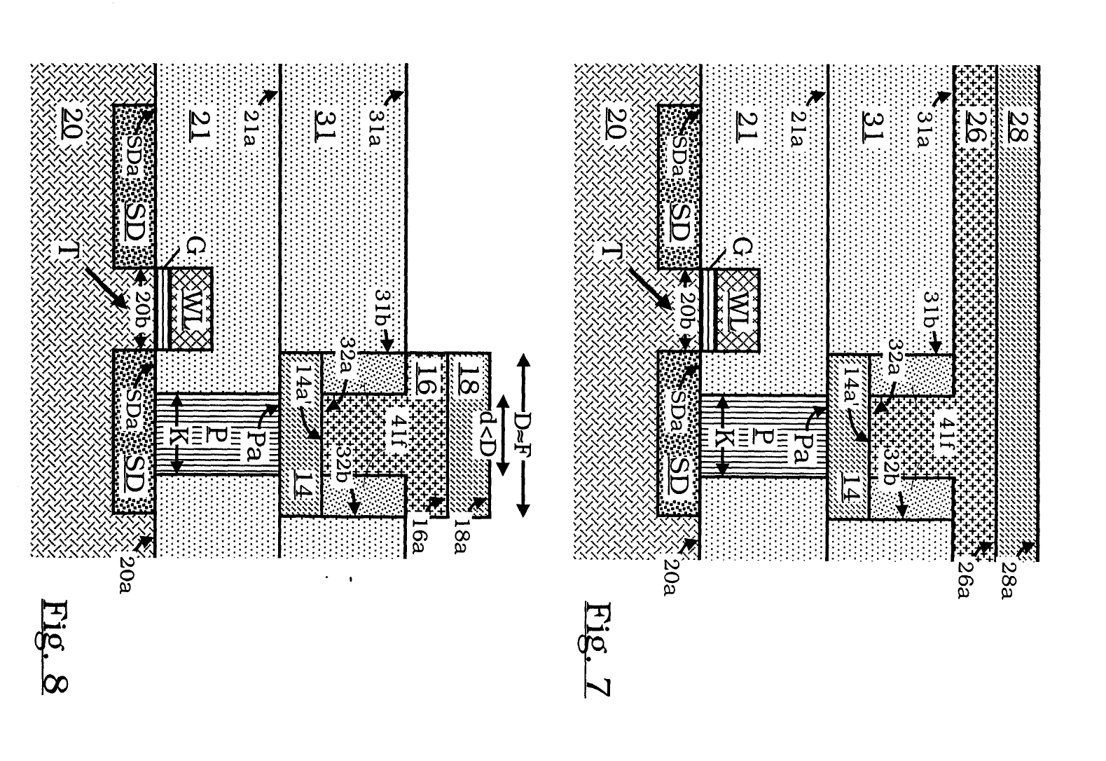

Referring now to the figures of the drawing in detail and first, particularly, to FIGS. 1A, 1B, 2B and 2A thereof, there is shown side, sectional views and plan views of a semiconductor memory device 1 which include a phase conversion storage element 10 and which have been fabricated by the inventive method (FIG. 1A, 1B) and by a conventional method (FIG. 2A, 2B), respectively.

In each of the two semiconductor memory devices 1, a non-illustrated CMOS or similar structure is provided in a semiconductor substrate 20 with a planar surface region 20a. For providing contact with the CMOS structure, a corresponding contact region or plug region P with surface region Pa is constructed in a first insulation layer or region 21 above the actual semiconductor substrate 20. A first or bottom access electrode 14 with a planar surface region 14a and a lateral extent D is provided in contact with the plug region P, respectively. The first access electrode 14 is constructed in and embedded in a second insulation layer or region 31. A recess 32, which is constructed as a contact hole, is filled with a corresponding storage medium 16 having a phase-dependent ohmic resistance and also includes a planar surface 16a.

As an alternative to the structure represented in FIGS. 1A to 2B, the storage medium 16 with the phase-dependent ohmic resistance can also contact a source/drain region of a selection transistor and/or similar device directly, so that, from a spatial perspective, the storage medium takes the place of the plug region P of FIGS. 1A to 2B, and the source/drain region of the selection transistor functions as the first electrode 14, and a metallic intermediate layer can also be provided.

Another alternative would be to construct the first and/or second electrodes 14, 18 as portions of access lines, for instance word lines and/or bit lines, whereby the selection transistor applying the electrical power could be forgone if the volume of the storage medium 16 undergoing phase conversion was sufficiently small.

It can be seen by comparing FIGS. 1A and 2B that in both cases the first or bottom access electrode 14 has a lateral extent D corresponding to the minimal feature size or structure size F of the utilized lithography technique: D=F. Potentially, the access electrode 14 can also be larger than the structural size F, e.g. 2F.

In the conventional fabrication method at the basis of the semiconductor memory device of FIGS. 2A, 2B, the overall free or open surface region 14a of the first access electrode 14 or the entire open area of the lithographically structured recess 32 is provided as a contact surface between the first access electrode 14 and the storage medium 16.

In contrast, in the memory device 1 of FIGS. 1A, 1B, corresponding spacer elements 41f are constructed in the second insulation layer 31 over part of the surface region 14a and over margin regions 32b of the recess 32 in the second insulation layer 31. As a result of the spacer elements 41f, only a sub-area 14a′ of the surface region 14a can serve as a contact area between the first access electrode 14 and the storage medium 16. The first access electrode 14 of the embodiment represented in FIGS. 1A, 1B also has a lateral extent D which corresponds to the minimal structural size F, but the contact region 14a′ and thus the spread of the storage medium 16 have a lateral extent d which is smaller than the minimum structural size F of the utilized lithography technique: d<D, F.

Accordingly, the material volume, which is to be converted, of the semiconductor memory device of FIGS. 1A, 1B is smaller than the material volume in the semiconductor device 1 of FIGS. 2A, 2B. Accordingly, in the embodiment of FIGS. 1A, 1B, the electrical or thermal energy that is to be applied is reduced such that it can also be applied by a MOSFET with a minimum structural size. The power needed for the phase conversion can potentially also be applied without a MOSFET, for instance over two crossing access lines.

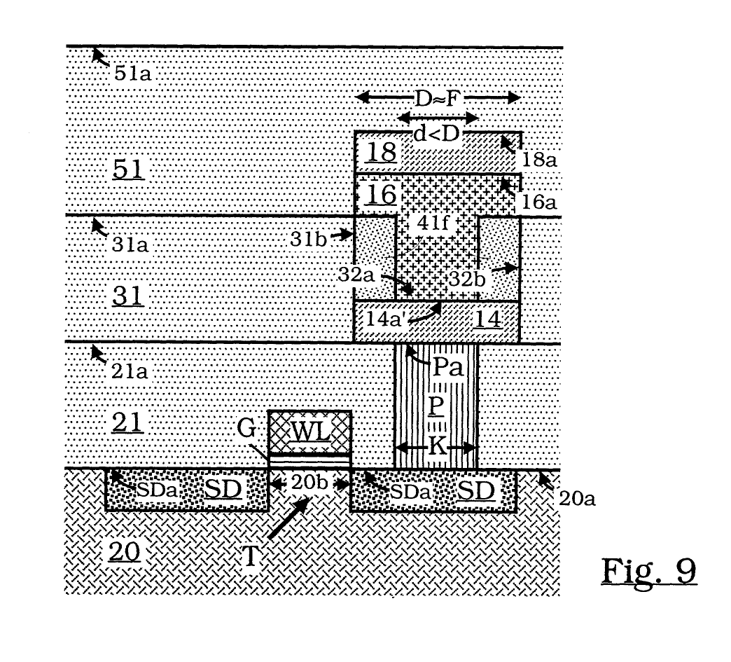

FIGS. 3 to 9 show side, sectional views of different intermediate stages in the fabrication of the semiconductor memory device 1 with a phase conversion storage effect according to a preferred embodiment of the invention.

The starting point for the embodiment of the inventive method represented in FIG. 3 is a base structure for the semiconductor memory device 1 that is to be fabricated, which substantially contains the semiconductor substrate 20 with the planar surface region 20a and, directly over this, the first insulation layer or region 21 with a planar surface region 21a. A non-illustrated CMOS structure is provided in the semiconductor substrate 20 for purposes of interconnecting the semiconductor memory device. A selection transistor T is provided for selecting the storage element 10. The selection transistor T is formed by two source/drain regions SD having a planar surface region SDa and are spatially separated by an intermediate region 20b and, above and between these, a gate oxide region G, which functions as a gate for the selection transistor T by way of a corresponding coupling through a word line WL. Embedded in the first insulation layer 21 such that it is in contact with the surface region SDa of the source/drain region SD and, by way of its own surface region Pa, with the surface 21a of the first insulation layer 21 is a contact region or plug region P for interconnecting the storage element 10 that is to be provided to the selection transistor T and the corresponding CMOS structure.

In direct contact with the surface region PA of the plug region P (i.e. at point K), the first or bottom access electrode 14 is constructed on the surface region 21a of the first insulation layer 21, which device has a lateral extent D that is somewhat larger than the minimum structural size F of the lithographic fabrication technique utilized for the first by access electrode 14.

A predefined position K for the plug region P and for the first access electrode 14 is predetermined by the position of the respective source/drain region SD, accordingly.

At the transition to the intermediate stage represented in FIG. 4, the first access electrode 14 is embedded in the second insulation layer 31 and covered by it. The first access electrode 14 is then at least partly exposed again by a corresponding lithographic etching step by the forming of a recess 32 with a floor region 32a and edge or margin regions 32b.

In the transition to the intermediate stage represented in FIG. 5, a material layer 41 of a spacer material for the spacer elements 41f that are to be constructed is deposited conformally and two-dimensionally. The surface region 31a of the second insulation layer 31, and the edge regions 31b, 32b and the floor region 32a of the formation 32, are covered by the spacer material 41.

In the transition to the intermediate stage of FIG. 6, an anisotropic or directional etching step is carried out, which is indicated by arrows in FIG. 5. The etching step substantially removes laterally extending material regions 41b of the material layer 41 for the spacer elements 41f from the surface region 31a of the second insulation layer 31 and the floor region 32a of the recess 32. From this, the freely accessible contact surface 14a′ emerges, which is reduced relative to the overall surface 14a of the first access electrode 14 to below the minimum structural size, the feature size F.

In the transition to the intermediate stage of FIG. 7, a material layer 26 for forming the storage medium 16 is then deposited in two-dimensional form and has a planar surface 26a. A material layer 28 for a second or top access electrode 18 is then constructed on the surface 26a of the material region 26 for the storage medium 16, preferably also two-dimensionally and with a planar surface 28a. Alternatively, the storage medium could be deposited and structured first, and then embedded.

In the transition to the intermediate stage of FIG. 8, the second or top access electrode 18 can be structured together with the storage medium 16 in accordance with the minimum structural size F of the applied lithography technique.

In the transition to the stage represented in FIG. 9, the overall structure that is achieved is embedded in a third insulation layer 51 having a surface 51a.

I claim:

1. A method for fabricating a semiconductor memory device having at least one memory cell with a phase conversion storage effect, which comprises the steps of:
providing a semiconductor substrate having a surface region and a first insulation layer disposed on the surface region; forming a first access electrode on the first insulation layer;
applying a second insulation layer which at least covers the first access electrode;
forming a recess in the second insulation layer such that at least a portion of a surface region of the first access electrode is exposed resulting in a freely accessible surface region;
performing a spacer technique for forming a spacer element at least along margin regions of the recess, the spacer element reducing a lateral extent of the recess and of the freely accessible surface region of the first access electrode, and the spacer element reduces a contact surface available to a storage medium to be provided;
filling the recess with a material for forming the storage medium, such that the material being in substantially conductive contact with the freely accessible surface region of the first access electrode; and
forming a second access electrode on the storage medium such that the storage medium is substantially between the first access electrode and the second access electrode, and the storage medium has a phase-dependent ohmic resistance in contact with the first and second access electrodes.

2. The method according to claim 1, which comprises forming the spacer element by applying a material layer in a substantially two-dimensional, conformal, surface-wide fashion, such that the margin regions and a floor region of the recess are substantially covered.

3. The method according to claim 2, which comprises etching back the material layer at least one of anisotropically and directionally for forming the spacer element, substantially laterally extending material regions of the material layer are thereby substantially removed from a surface region of the second insulation layer and the floor region of the recess, and substantially vertically extending material regions of the material layer remain forming the spacer element.

4. The method according to claim 2, which comprises depositing the material layer for the spacer element by a deposition technique selected from the group consisting of an isotropic deposition and a conformal deposition.

5. The method according to claim 2, which comprises forming the material layer from a material selected from the group consisting of SiO₂, BPSG, a photo imide, and Si₃N₄.

6. The method according to claim 1, which comprises forming the spacer element with a thickness less than half a maximum ~lateral extent of the recess in the second insulation layer.

7. The method according to claim 1, which comprises forming the first access electrode with a limited lateral extent which at least substantially corresponds to a feature size of a utilized technique selected from the group of lithography techniques and etching techniques.

8. The method according to claim 7, which comprises:
depositing a material layer on the first insulating layer, in a substantially two-dimensional, surface-wide form; and
partially removing the material layer by a technique selected from the group consisting of a lithography technique and an etching technique, resulting in the first access electrode being formed at a defined location.

9. The method according to claim 8, which comprises:
forming a contact region in the first insulating layer, the contact region provided for contacting an access line device of a selection device; and
setting a location selected as the defined location to be a region directly above and in contact with a surface region of the contract region.

10. The method according to claim 1, which comprises forming the first access electrode as a part of a source/drain region of a selection device, whereby a conductive intermediate layer is constructed.

11. The method according to claim 1, which comprises forming first and second access lines for accessing the memory cell, a portion of the first access line being formed by the first access electrode and a portion of the second access line formed by the second access electrode.

12. The method according to claim 1, which comprises forming the memory cell as one of a plurality of memory cells organized in a layered fashion in several storage layers which are stacked substantially directly on top of one another.

13. The method according to claim 1, which comprises forming the spacer element with a thickness less than half a structural size of a utilized lithography or etching technique.

14. The method according to claim 10, which comprises forming the selection device as a MOSFET.

15. The method according to claim 11 which comprises:
forming a source/drain region of a selection device in the semiconductor substrate; and
forming a conductive intermediate layer connecting the source/drain region to the first access electrode.

16. The method according to claim 11, which comprises:
forming the first access line as a word line;
forming the second access line as a bit line; and
forming the first access electrode and the second access electrode at a cross over point of the first and second access lines.

17. A semiconductor memory device, comprising:
a semiconductor substrate having a surface;
a first insulating layer disposed on said semiconductor substrate;
a first access electrode disposed on said first insulating layer;
a second insulating layer disposed on said first insulating layer and covers said first access electrode, said second insulating layer having a recess formed therein in an area of said first access electrode and uncovering a free surface area of said first access electrode;
a spacer element disposed at least on edge regions of said recess such that a lateral extent of said recess and of said free surface area of said first access electrode, emerge reduced, to a value below a minimum structural size of an applied technique used selected from the group consisting of a lithograph technique and an etching technique;
a material functioning as a storage medium having a phase-dependent ohmic resistance filling said recess, said storage medium being in conductive contact with said free surface area of said first access electrode; and
a second access electrode disposed on said storage medium, said first access electrode, said storage medium and said second access electrode defining a storage element.

18. The semiconductor memory device according to claim 17, wherein said spacer element is composed of a material selected from the group consisting of SiO₂, BPSG, a photo imide, and Si₃N₄.

19. The semiconductor memory device according to claim 17, wherein said first access electrode has a limited lateral extent substantially corresponding to the minimum structural size of the applied technique used.

20. The semiconductor memory device according to claim 17, wherein said first access electrode functions as at least part of a source/drain region of a selection device, whereby a conductive intermediate layer is constructed.

21. The semiconductor memory device according to claim 17, further comprising a first and second access line for accessing said storage element, a portion of said first access line formed by said first access electrode and a portion of said second access line formed by said second access electrode device.

22. The semiconductor memory device according to claim 21, wherein:
said first access line is a word line;
said second access line is a bit line; and
said first access electrode and said second access electrode
are formed at cross over points of said word line and said bit line.

23. The semiconductor memory device according to claim 17, wherein said storage element is one of a plurality of storage elements organized in a layered fashion in several storage layers which are stacked substantially directly on top of one another.

24. The semiconductor memory device according to claim 20, wherein said selection device is a MOSFET.

25. A semiconductor memory device, comprising:
a semiconductor substrate having a surface;
a first access electrode disposed in said semiconductor substrate and functioning as part of a source/drain region of a selection transistor;
an insulating layer disposed on said semiconductor substrate covering said first access electrode, said insulating layer having a recess formed therein in an area of said first access electrode and uncovering a free surface area of said first access electrode;
a spacer element disposed at least on edge regions of said recess such that a lateral extent of said recess and of said free surface area of said first access electrode, emerge reduced, to a value below a minimum structural size of an applied technique used selected from the group consisting of a lithograph technique and an etching technique;
a material functioning as a storage medium having a phase-dependent ohmic resistance filling said recess, said storage medium being in conductive contact with said free surface area of said first access electrode; and
a second access electrode disposed on said storage medium, said first access electrode, said storage medium and said second access electrode defining a storage element.

26. A method for fabricating a semiconductor memory device having at least one memory cell with a phase conversion storage effect, which comprises the steps of:
providing a semiconductor substrate having a surface region;
forming a first access electrode in the semiconductor substrate and the first access electrode functioning as part of a source/drain region of a selection transistor;
applying an insulation layer on the semiconductor substrate which at least covers the first access electrode;
forming a recess in the insulation layer such that at least a portion of a surface region of the first access electrode is exposed resulting in a freely accessible surface region;
performing a spacer technique for forming a spacer element at least along margin regions of the recess, the spacer element reducing a lateral extent of the recess and of the freely accessible surface region of the first access electrode, and the spacer element reduces a contact surface available to a storage medium to be provided;
filling the recess with a material for forming the storage medium, such that the material is in substantially conductive contact with the freely accessible surface region of the first access electrode; and
forming a second access electrode on the storage medium such that the storage medium is substantially between the first access electrode and the second access electrode, and the storage medium has a phase-dependent ohmic resistance in contact with the first and second access electrodes.
